(19) United States
(12) Patent Application Publication
(10) Pub. No.: US 2009/0151638 A1
(43) Pub. Date: Jun. 18, 2009

(54) PLASMA PROCESSING APPARATUS

(75) Inventors: Toshiki KOBAYASHI, Tsukui-gun (JP); Masaki Sugiyama, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/331,596

(22) Filed: Dec. 10, 2008

(30) Foreign Application Priority Data
Dec. 14, 2007 (JP) 2007-323872

(51) Int. Cl. C23C 16/513

(52) U.S. Cl. 118/723 R

(57) ABSTRACT

A plasma processing apparatus includes: a lift mechanism which, in a process vessel, moves down a stage to a standby position when plasma processing is not performed and moves up the stage to a processing position when the plasma processing is performed; a holding member detachably holding a mask which is to cover an outer peripheral edge portion of the substrate, between the standby position and the processing position; and a positioning mechanism positioning the mask on the stage, wherein: the mask is held while being horizontally movable without being positioned by the holding member; and when the stage is moved up from the standby position toward the processing position, the mask is transferred from the holding member onto the stage, and the mask is positioned on the stage by the positioning mechanism.

### BACKGROUND OF THE INVENTION

1. Field of the Invention

The present invention relates to a plasma processing apparatus applying a process such as film forming to a substrate by turning process gas into plasma.

2. Description of the Related Art

For example, in manufacturing fields of LCD substrates, semiconductors, and the like, a film forming process using a CVD method as an example of plasma processing is performed. In such a film forming process, in order to form a non-film-forming region in an outer peripheral edge portion of a glass substrate or a semiconductor wafer, the outer peripheral edge portion of the substrate is covered by a mask (shadowing) during the plasma processing. Such masking enables the formation of the non-film-forming region in the outer peripheral edge portion of the substrate to make effective use of the non-film-forming region as a wiring region or the like, and also enables the prevention of the generation of particles in what is called a bevel portion, and so on. Further, as an apparatus performing such masking, there has conventionally been known a plasma processing apparatus in whose process vessel, a mask is disposed above a stage for having a substrate placed thereon and the mask is overlaid on an peripheral edge portion of the substrate as the stage is moved up (see International Publication WO2004/097919).

### SUMMARY OF THE INVENTION

In order to improve yields, an area of the non-film-forming region thus formed in the outer peripheral edge portion of the substrate by the masking is desirably as small as possible. For this, accurate positioning of the mask covering the outer peripheral edge portion of the substrate is important. In the recent standard, it is considered desirable that a width of the non-film-forming region formed in the outer peripheral edge portion of the substrate by the masking is, for example, about 1 mm to about 10 mm from an outer peripheral edge of the substrate. Further, considering a conveyance error or the like of the substrate, positioning precision of the mask is desirably about 2 mm or less, for instance. Positioning the mask relative to an inner surface of the process vessel is one possible method to achieve this precision.

However, the positional relation between the process vessel and the stage of the plasma processing apparatus is not completely fixed, and is varied among processing apparatuses depending on, for example, subtle assembly conditions and the like thereof. Further, the process vessel and the stage both thermally expand during the plasma processing, and amounts of the thermal expansion of the process vessel and the stage differ depending on process conditions and the like of the plasma processing performed in the process vessel, and thus the positional relation between the process vessel and the stage changes. In particular, recent plasma processing apparatuses have been formed larger, and for example, in a G4.5 (4.5 generation) plasma processing apparatus (size of a processed substrate: 730 mm×920 mm), the area of the stage is about 780 mm×about 970 mm and the plane area of the process vessel is about 1100 mm×about 1300 mm. Further, in a G8 plasma processing apparatus, a processed substrate has a still larger size of 2200 mm×2600 mm. Therefore, if the mask is positioned relative to the inner surface of the process vessel as has been done conventionally, it has become difficult to accurately position the mask covering the outer peripheral edge portion of the substrate, due to the deviation of the positional relation between the process vessel and the stage.

It is an object of the present invention to provide a plasma processing apparatus realizing accurate positioning of a mask covering an outer peripheral edge portion of a substrate.

Studies on the positioning of a mask by the present inventors have led to the finding that, by the method of positioning the mask relative to the inner surface of the process vessel, it is now difficult to achieve the positioning of the mask which satisfies the recent standard requiring the formation of the non-film-forming region, which is formed in the outer peripheral edge portion of the substrate by masking, in a range of about 1 mm to about 10 mm from the outer peripheral edge of the substrate with high precision of about 2 mm or less, for instance. Moreover, it has been found out that, if the mask is positioned relative to the inner surface of the process chamber, the deviation of the positional relation between the process chamber and the stage of the plasma processing apparatus prevents accurate positioning of the mask all the more. Then, as a result of pursuing the studies, the present inventors have reached a novel and unique finding that, in order to realize accurate positioning of the mask with precision satisfying the recent standard, it is better to position the mask on the stage while allowing the mask to horizontally move relative to the inner surface of the process vessel, rather than positioning the mask relative to the inner surface of the process vessel, and only by this method, high-precision positioning of the mask satisfying the recent standard is enabled.

The present invention was created based on such findings. Specifically, according to the present invention, there is provided a plasma processing apparatus which applies plasma processing to a substrate placed on a stage by turning process gas supplied into a process vessel into plasma, the apparatus including: a lift mechanism which, in the process vessel, moves down the stage to a standby position when the plasma processing is not performed and moves up the stage to a processing position when the plasma processing is performed; a holding member detachably holding a mask which is to cover an outer peripheral edge portion of the substrate, between the standby position and the processing position; and a positioning mechanism positioning the mask on the stage, wherein the mask is held while being horizontally movable without being positioned by the holding member, and when the stage is moved up from the standby position toward the processing position, the mask is transferred from the holding member onto the stage, and the mask is positioned on the stage by the positioning mechanism.

According to this plasma processing apparatus, it is possible to accurately position the mask on the stage by the positioning mechanism without affected by the deviation of the positional relation between the process vessel and the stage of the plasma processing apparatus. Further, since the mask is held while being horizontally movable without being positioned by the holding member, the mask is freely movable relative to the holding member at the time of the positioning of the mask, which enables smooth positioning of the mask.

In the plasma processing apparatus, the positioning mechanism may be made up of a taper pin provided on an upper surface of the stage and a guide hole provided in the mask to have the taper pin inserted therein. Further, the guide hole may be provided in plurality, and at least part of the guide holes may be in a long hole shape. Further, the mask may be made up of a plurality of divided mask members. In this case, end portions of the plural divided mask members may be arranged to be laid one on the other vertically.

Further, the holding member may be fixed to an inner surface of the process vessel.

Further, the holding member may be made up of: a baffle holding member fixed to an inner surface of the process vessel; and a baffle plate detachably supported by the baffle holding member, and when the stage is moved up from the standby position toward the processing position, the baffle plate may be transferred onto the stage from the baffle holding member. In this case, the baffle plate may be supported while being positioned relative to the inner surface of the process vessel.

Further, a recession for having the substrate placed thereon may be formed in an upper surface of the stage.

According to the present invention, it is possible to accurately position a mask which is to cover an outer peripheral portion of a substrate, and accordingly, it is possible to satisfy a recent high standard required for masking.

### BRIEF DESCRIPTION OF THE DRAWINGS

FIG. 1 is a schematic vertical sectional view for explaining a plasma processing apparatus according to a first embodiment of the present invention;

FIG. 2(a) is a cross-sectional view taken along X-X in FIG. 1, and FIG. 2(b) is an enlarged cross-sectional view taken along Y-Y in FIG. 2(a) and shows a state where a mask is supported on a stage;

FIG. 3 is an explanatory view of a mask;

FIGS. 4(a) and 4(b) are explanatory views of longitudinal end portions of mask members, FIG. 4(a) being a perspective view showing a state where the end portions are separated from each other and FIG. 4(b) being a plane view showing a state where the end portions are laid one on the other;

FIG. 5 is an explanatory view of a positional relation among the stage, a substrate, and the mask in a state where the stage is down at a standby position;

FIG. 6 is an explanatory view of a positional relation among the stage, the substrate, and the mask in a state where the mask has been transferred onto the stage;

FIG. 7 is an explanatory view of a positional relation among the stage, the substrate, and the mask in a state where the stage is up at a processing position;

FIG. 8 is a schematic vertical cross-sectional view for explaining a plasma processing apparatus according to a second embodiment of the present invention;

FIG. 9 is a cross-sectional view taken along X-X in FIG. 8;

FIG. 10 is an explanatory view of a positional relation among a stage, a substrate, a mask, and a baffle plate in a state where the stage is down at a standby position;

FIG. 11 is an explanatory view of a positional relation among the stage, the substrate, the mask, and the baffle plate in a state where the mask has been transferred onto the stage;

FIG. 12 is an explanatory view of a positional relation among the stage, the substrate, the mask, and the baffle plate in a state where the stage is up at a processing position; and

FIG. 13 is an explanatory view of longitudinal end portions of mask members according to a modification example.

### DETAILED DESCRIPTION OF THE INVENTION

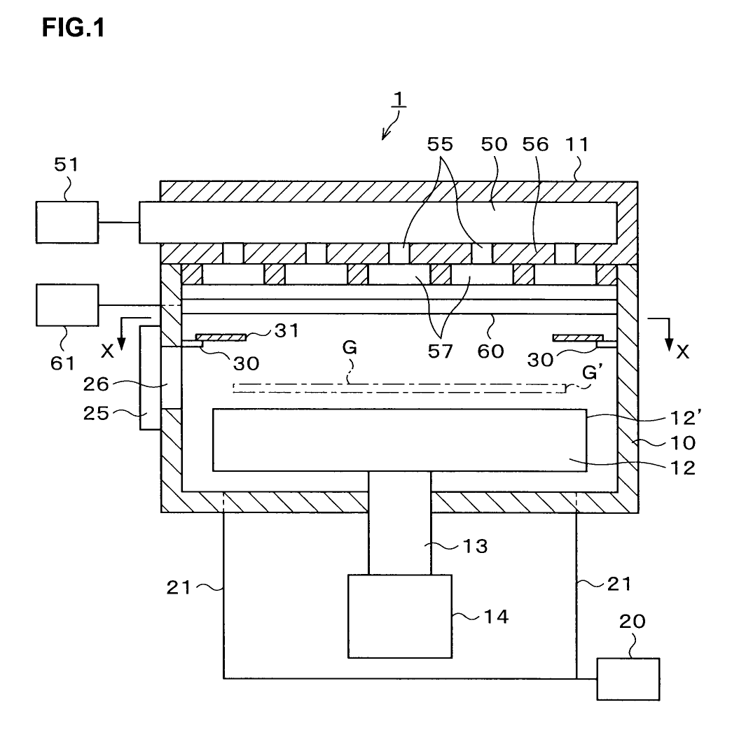

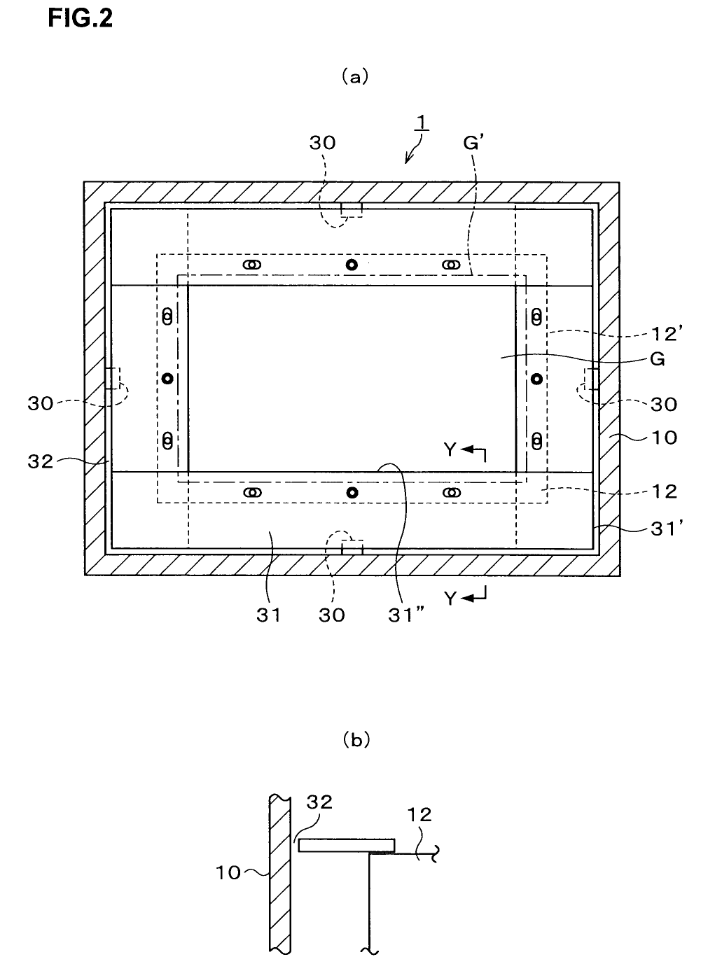

Hereinafter, embodiments of the present invention will be described based on a plasma processing apparatus 1 applying a CVD (chemical vapor deposition) process as an example of plasma processing to a glass substrate (hereinafter, referred to as “a substrate”) G. FIG. 1 is a schematic vertical cross-sectional view for explaining the plasma processing apparatus 1 according to a first embodiment of the present invention. FIG. 2(a) is a cross-sectional view taken along X-X in FIG. 1. FIG. 2(b) is an enlarged cross-sectional view taken along Y-Y in FIG. 2(a) and shows a state where a mask 31 is supported on a stage 12. In the specification and the drawings, constituent elements having substantially the same functional structure will be denoted by the same reference numerals and symbols and redundant description thereof will be omitted.

The plasma processing apparatus 1 includes: an airtight process vessel 10 in a bottomed cubic shape with an upper portion thereof opened; and a cover 11 covering an upper side of the process vessel 10. The process vessel 10 and the cover 11 are made of aluminum, for instance, and are both grounded.

Inside the process vessel 10, the stage 12 as a mounting table for having the substrate G placed thereon is provided. As shown in FIG. 2(a), the substrate G and the stage 12 are both in a rectangular shape in a plane view, and an outer peripheral edge 12′ of the stage 12 is on an outer side of an outer peripheral edge G′ of the substrate G.

A center of a lower surface of the stage 12 is supported by an upper end of a support post 13 penetrating through a bottom surface of the process vessel 10, and a lift mechanism 14 disposed outside the process vessel 10 is provided on a lower end of the support post 13. By the operation of the lift mechanism 14, in the process chamber 10, the stage 12 is moved down to a standby position when the plasma processing is not performed and is moved up to a processing position when the plasma processing is performed. FIG. 1 shows a state when the plasma processing is not performed, that is, a state where the stage 12 is down at the standby position.

The stage 12 is made of carbon, aluminum nitride, or the like, for instance, and in the stage 12, there is provided, though not shown, a power supply part electrostatically attracting the substrate G and applying a predetermined bias voltage to the inside of the process vessel 10, a heater heating the substrate G to a predetermined temperature, and so on.

An exhaust circuit 21 through which an atmosphere in the process vessel 10 is exhausted by an exhaust device 20 such as a vacuum pump provided outside the process vessel is connected to the bottom of the process vessel 10.

On a side surface of the process vessel 10, an opening 26 opened/closed by a gate valve 25 is provided. When the opening 26 is opened by the gate valve 25, the substrate G placed on a carrier arm is carried into the process vessel 10, and the substrate G is held above the stage 12, which has been moved down to the standby position, by holding pins, not shown, projecting on the stage 12.

Further above the substrate G thus held above the stage 12, a mask 31 is placed on holding members 30 fixed to an inner wall of the process vessel 10 and thus is disposed inside the process vessel 10. The mask 31 is detachably held by the holding members 30 between an upper surface of the stage 12 which is down at the standby position and the upper surface of the stage 12 which is up at the processing position.

The holding members 30 do not obstruct the up/down movement of the stage 12 since the holding members 30 are on an outer side of the stage 12 as shown in FIG. 2(a). The mask 31 has a frame shape so as to cover an outer peripheral edge portion of the substrate G but expose a center portion of the substrate G when it is put on the substrate G. An outer peripheral edge 31′ of the mask 31 is on an outer side of the outer peripheral edge 12′ of the stage 12. Therefore, it is possible to hold the mask 31, with a rear surface of the mask 31 placed on the holding member 30 on an outer side of the stage 12, when the stage 12 is down at the standby position.

Between the outer peripheral edge 31′ of the mask 31 and an inner wall surface of the process vessel 10, a predetermined gap 32 is formed. By adjusting the size of the gap 32, the flow of gas in the process vessel 10 is regulated. Therefore, in the plasma processing apparatus 1 according to the first embodiment, the outer peripheral edge 31′ of the mask 31 has a function of a baffle plate.

While the mask 31 is held by the holding members 30, the mask is not positioned relative to the holding members 30 but is held on the holding members 30 to be horizontally movable.

An inner peripheral edge 31″ of the mask 31 is on an inner side of the outer peripheral edge G′ of the substrate G. Therefore, by putting the mask 31 on the substrate G, it is possible to cover the peripheral edge portion of the substrate G by the mask 31.

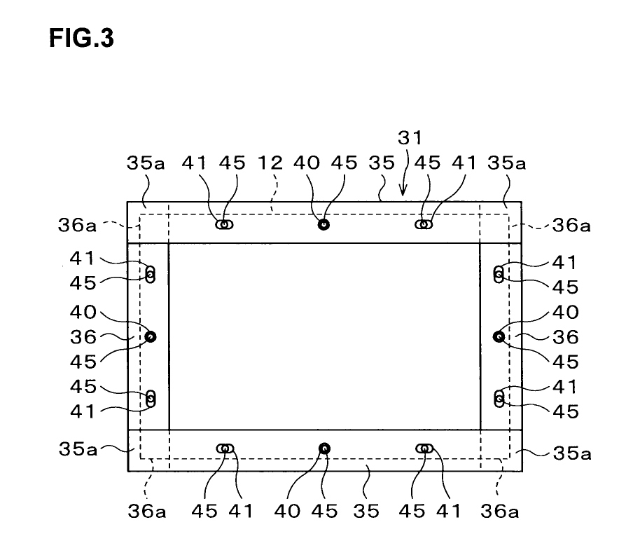

As shown in FIG. 3, the mask 31 has a pair of mask members 35 forming longer sides of the frame shape and a pair of mask members 36 forming shorter sides thereof. In each of the mask members 35, 36, a circular guide hole 40 located at the center thereof and guide holes 41 in a long hole shape located on both sides of the circular guide hole 40 are opened. A longitudinal direction of the guide holes 41 in a long hole shape matches the longitudinal direction of each of the mask members 35, 36.

On the upper surface of the stage 12, taper pins 45 inserted in the circular guide holes 40 and the guide holes 41 in a long hole shape provided in the mask members 35, 36 are provided at a plurality of places corresponding to the circular guide holes 40 and the guide holes 41 in a long hole shape. When the mask 31 is to be laid on the substrate G placed on the upper surface of the stage 12, the taper pins 45 are inserted in the circular guide holes 40 and the guide holes 41 in a long hole shape, thereby positioning the mask 31. Since upper half portions 45′ of the taper pins 45 are in a conical shape as will be described later, it is possible to move the mask members 35, 36 to desired positions and position the mask 31 by inserting the taper pins 45 from under into the circular guide holes 40 and the guide holes 41 in a long hole shape.

Incidentally, the mask members 35, 36 sometimes change in length due to their thermal expansion on the upper surface of the stage 12. Even when such thermal expansion occurs, the state where the taper pins 45 are inserted in the circular guide holes 40 and the guide holes 41 in a long hole shape is maintained since the taper pins 45 are movable in the guide holes 41 in a long hole shape provided in the mask members 35, 36. This makes it possible to favorably maintain the state where the mask members 35, 36 are positioned on the stage 12.

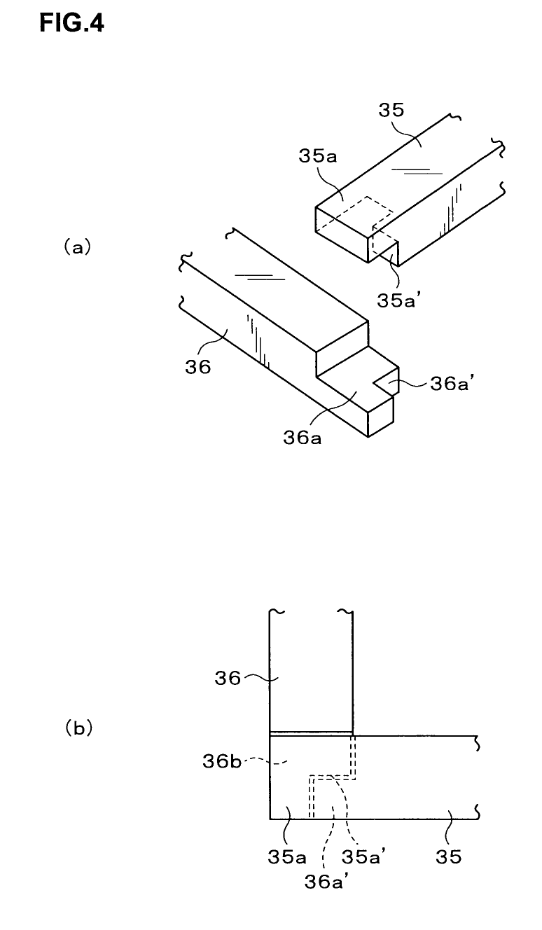

As shown in FIGS. 4(a) and 4(b), longitudinal end portions 35a, 36a of the mask members 35, 36 are arranged to be laid one on the other vertically. Therefore, on the upper surface of the stage 12, even when the mask members 35, 36 change in length due to the thermal expansion, the longitudinal end portions 35a, 36a of the mask members 35, 36 are always kept laid one on the other, so that the mask 31 can maintain its frame shape.

In the example shown in FIGS. 4(a) and 4(b), a protrusion 35a′ is provided in one of the end portions 35a, 36a of the mask members 35, 36 and a recession 36a′ is provided in the other, and when the end portions 35a, 36a of the mask members 35, 36 are laid one on the other vertically, the protrusion 35a′ enters the inside of the recession 36a′. In this case, since joint surfaces of the end portions 35a, 36a of the mask members 35, 36 are not in a planar shape, an amount of gas entering a gap between the end portions 35a, 36a is reduced, which makes it possible to effectively prevent the entrance of the gas to the outer peripheral edge of the substrate G.

A plurality of waveguides 50 parallel to one another are formed inside the cover 11. The waveguides 50 are, what is called, rectangular waveguides each having a rectangular cross section. Further, a dielectric such as, for example, Al₂O₃, quartz, or fluorocarbon resin, is filled in the waveguides 50. A microwave of, for example, 2.45 GHz generated in a microwave supply apparatus 51 provided outside the process vessel 10 is introduced to the waveguides 50.

A lower surface of the cover 11 is a slot antenna 56 having a plurality of slots 55. Further, a plurality of dielectrics 57 corresponding to the slots 55 are attached to a lower surface of the slot antenna 56. The dielectrics 57 are made of, for example, quartz glass, AlN, Al₂O₃, sapphire, SiN, ceramics, or the like.

In an upper portion in the process vessel 10, a shower plate 60 is provided. The shower plate 60 is made of a hollow tube member made of, for example, a quartz tube, an alumina tube, or the like. A plurality of openings, though not shown, through which process gas is supplied to the substrate G on the stage 12 are provided in the shower plate 60 in a distributed manner. A process gas supply source 61 disposed outside the process vessel 10 is connected to the shower plate 60. The process gas supply source 61 contains, for example, silane gas, TEOS, nitrogen, Ar, oxygen, and so on as the process gas. The process gas is introduced into the shower plate 60 from the process gas supply source 61, and the process gas is supplied into the process vessel 10 in a uniformly dispersed state.

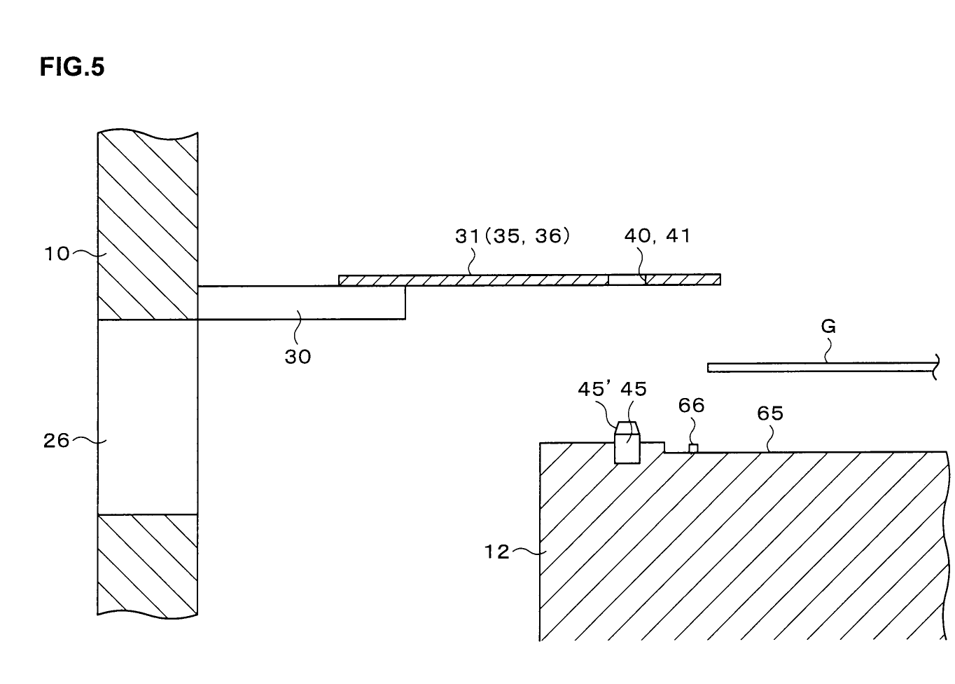

Then, a description will be given of a case, for instance, where an amorphous silicon film is formed on the substrate G in the plasma processing apparatus 1 according to the first embodiment of the present invention as structured above. First, the opening 26 is opened and the substrate G is carried into the process vessel 10. Then, as shown in FIG. 5, the substrate G is held above the stage 12 which is down at the standby position.

After the substrate G is thus carried in, the stage 12 is moved up from the standby position toward the processing position by the operation of the lift mechanism 14. In the course of this upward movement, the substrate G is first transferred onto the stage 12. In this case, the substrate G is placed on a recession 65 formed in a center portion of the upper surface of the stage 12. Further, the substrate G is positioned by a projection 66 provided on the recession 65.

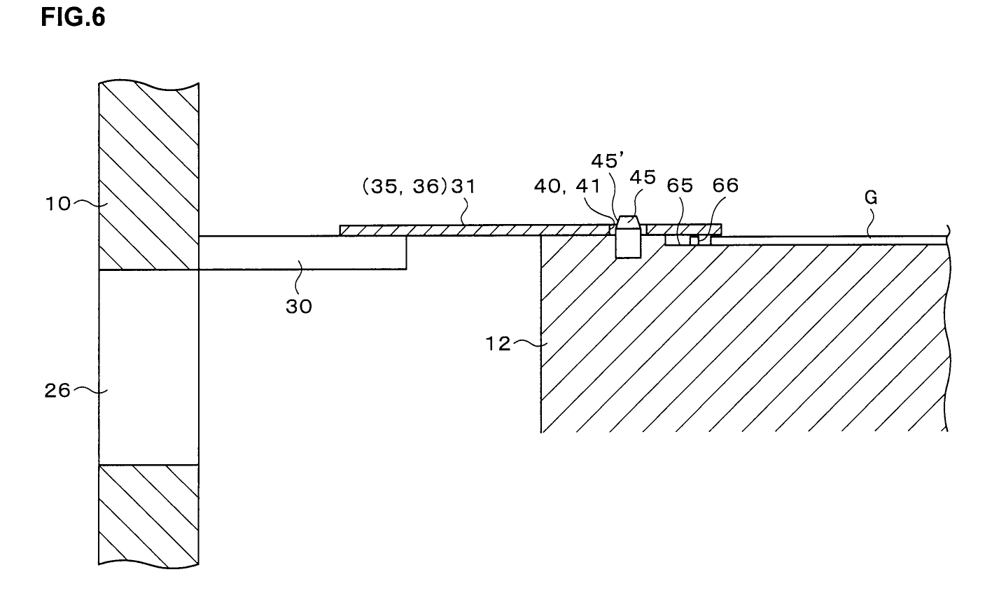

After the substrate G is thus transferred onto the stage 12, the stage 12 is moved up again, and as shown in FIG. 6, the taper pins 45 provided on the upper surface of the stage 12 are inserted from under to the circular guide holes 40 and the guide holes 41 in a long hole shape provided in the mask members 35, 36. Consequently, the mask members 35, 36 move along the conical upper half portions 45′ of the taper pins 45, so that the mask 31 is positioned. As a result of such positioning of the mask 31, the outer peripheral edge portion of the substrate G placed on the stage 12 is covered by the mask 31.

In this case, while placed on the holding members 30, the mask 31 is held to be horizontally movable on the holding members 30. Therefore, when the taper pins 45 provided on the upper surface of the stage 12 are thus inserted in the circular guide holes 40 and the guide holes 41 in a long hole shape provided in the mask members 35, 36, the mask members 35, 36 are smoothly moved to predetermined positions on the stage 12. In this manner, the mask 31 is accurately positioned, which makes it possible to accurately cover the outer peripheral edge portion of the substrate G by the mask 31 with precision of, for example, about 1 mm to about 2 m relative to the outer peripheral edge of the substrate G.

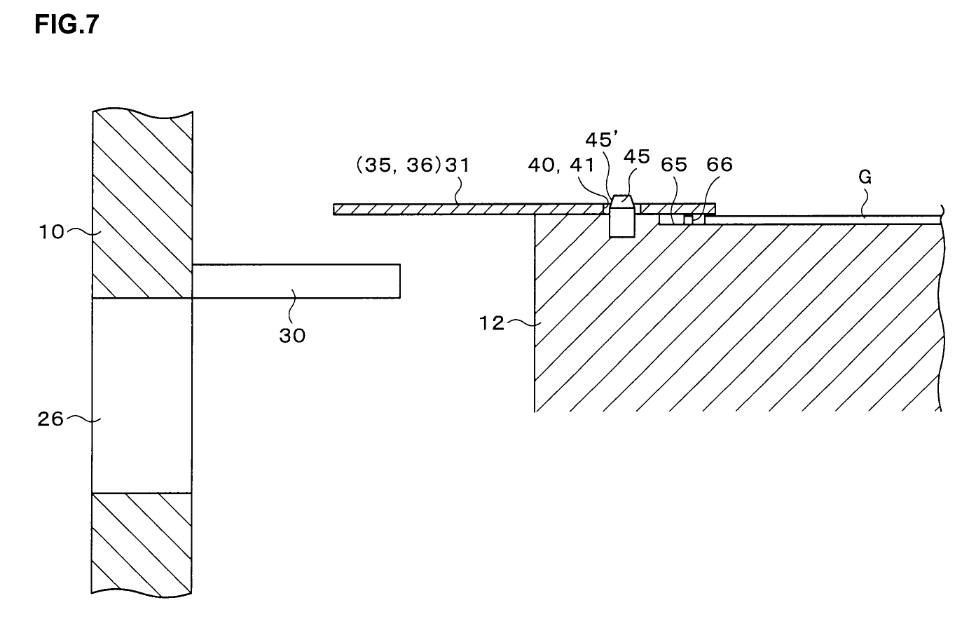

Then, when the stage 12 is moved up to the processing position by the operation of the lift mechanism 14, the mask 31 is moved up from the holding members 30 to be supported while being positioned on the stage 12 as shown in FIG. 7.

Thereafter, the process gas is supplied into the process vessel 10 through the shower plate 60 in a uniformly dispersed state. Further, the microwave of, for example, 2.45 GHz is introduced from the waveguides 50 into the process vessel 10 via the plural dielectrics 57. In this manner, the process gas is turned into plasma in the process vessel 10, and the amorphous silicon film is formed on the surface of the substrate G.

Then, after the formation of the amorphous silicon film is finished, the supply of the process gas and the introduction of the microwave are stopped. Then, the stage 12 is moved down from the processing position to the standby position by the operation of the lift mechanism 14. This produces again the state where the mask 31 is placed on the holding members 30 and the substrate G is held above the stage 12 as shown in FIG. 5. Thereafter, the opening 26 is opened and the substrate G is carried out of the process vessel 10.

According to the plasma processing apparatus 1 of the first embodiment, it is possible to accurately position the mask 31 on the stage 12 without affected by the deviation of the positional relation between the process vessel 10 and the stage 12. This makes it possible to accurately form a non-film-forming region in the outer peripheral edge portion of the substrate G with precision of, for example, about 1 mm to about 2 mm relative to the outer peripheral edge of the substrate G.

Since the substrate G is placed on the recession 65 formed in the center portion of the stage 12 as shown in FIG. 5, it is possible to prevent a rear surface of the mask 31 held on the stage 12 from coming into contact with an upper surface of the substrate G. Therefore, even when, for example, the mask members 35, 36 change in length due to the thermal expansion, it is possible to prevent the upper surface of the substrate G and the rear surfaces of the mask members 35, 36 from rubbing against each other, enabling the protection of the outer peripheral edge portion of the substrate G. Further, owing to the positioning by the projection 66, it is possible to hold the substrate G at a predetermined position in the recession 65. It is also possible to adjust the distance between the upper surface of the substrate G and the rear surfaces of the mask members 35, 36 depending on the height of the projection 66. Adjusting the distance between the upper surface of the substrate G and the rear surfaces of the mask members 35, 36 makes it possible, for example, to prevent the flow of the gas into the gap therebetween and thus prevent the film formation there, and also facilitates temperature control of the substrate G.

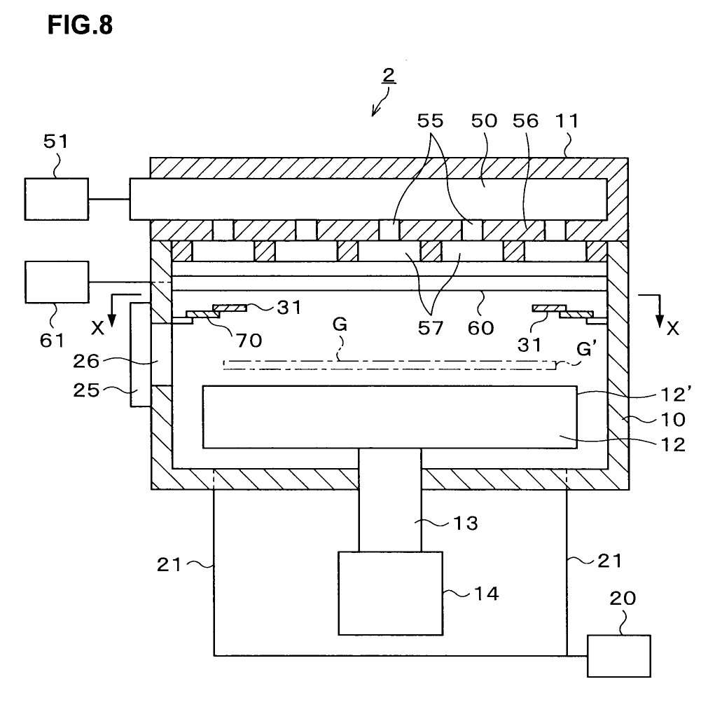

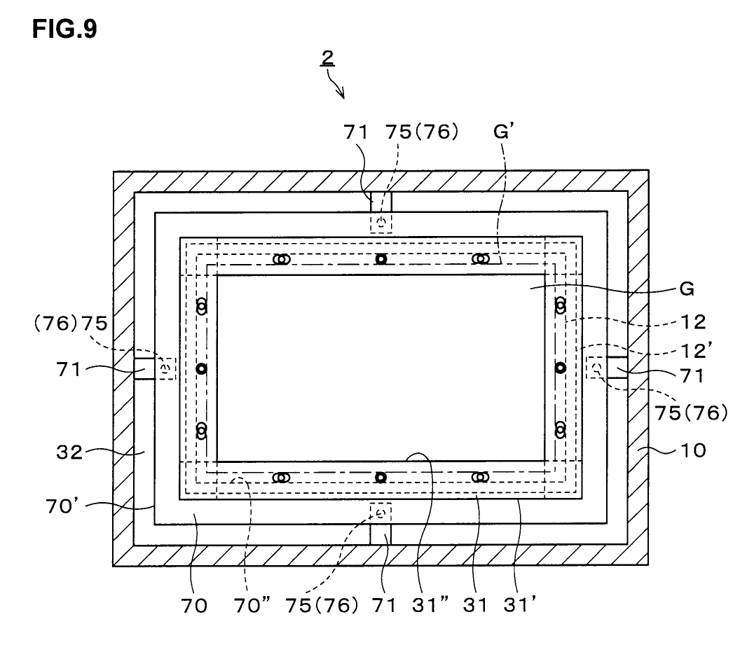

Next, a plasma processing apparatus 2 according to a second embodiment of the present invention will be described. FIG. 8 is a schematic vertical cross-sectional view for explaining the plasma processing apparatus 2 according to the second embodiment of the present invention. FIG. 9 is a cross-sectional view taken along X-X in FIG. 8. The constituent elements already described will be denoted by the same reference numerals and symbols and redundant description thereof will be omitted.

In the plasma processing apparatus 2, a holding member holding a mask 31 is made up of a baffle plate 70 for regulating the flow of gas in a process vessel 10 and baffle plate holding members 71. The plasma processing apparatus 2 is the same as the plasma processing apparatus 1 according to the first embodiment of the present invention previously described in that the mask 31 is held while being horizontally movable without being positioned relative to the holding member (the baffle plate 70 and the baffle plate holding members 71).

By being placed on the baffle plate holding members 71 fixed to an inner wall of the process vessel 10, the baffle plate 70 is disposed further above the substrate G held above a stage 12 at a standby position. Consequently, the baffle plate 70 is supported to be separable from the inner surface of the process vessel 10, and when the stage 12 is moved up from the standby position toward a processing position, the baffle plate 70 is transferred onto the stage 12.

Protrusions 75 are provided on upper surfaces of the baffle plate holding members 71, and recessions 76 receiving the protrusions 75 are provided on a rear surface of the baffle plate 70. When the baffle plate 70 is on the baffle plate holding members 71, the baffle plate 70 is positioned relative to the inner surface of the process vessel 10 by the engagement of the projections 75 and the recessions 76.

When the stage 12 is at the standby position, the mask 31 is on the baffle plate 70. However, between the mask 31 and the baffle plate 70, no mechanism restricting the mutual positional relation is provided. Therefore, the mask 31 is held while being horizontally movable without being positioned relative to the baffle plate 70 and the baffle plate holding members 71.

In an outer peripheral edge portion of the stage 12, a stepped portion 80 formed lower than an upper surface of the stage 12 is formed. A distance (depth) D from the upper surface of the stage 12 to the stepped portion 80 is set larger than a thickness 70d of the baffle plate 70 (D>70d).

The baffle plate holding members 71 do not obstruct the up/down movement of the stage 12 since the baffle plate holding members 71 are on an outer side of the stage 12 as shown in FIG. 9. The baffle plate 70 has a frame shape so as to be put on the stepped portion 80 formed in the outer peripheral edge portion of the stage 12. However, unlike the mask 31 divided into the plural mask members 35, 36, the baffle plate 70 is not divided but is integrally formed.

An outer peripheral edge 70′ of the baffle plate 70 is on an outer side of an outer peripheral edge 12′ of the stage 12. Therefore, when the stage 12 is down at the standby position, it is possible to hold the baffle plate 70 with a rear surface of the baffle plate 70 placed on the baffle plate holding members 71 outside the stage 12.

A predetermined gap 32 is formed between the outer peripheral edge 70′ of the baffle plate 70 and the inner wall surface of the process vessel 10. By adjusting the size of the gap 32, the flow of gas in the process vessel 10 is regulated.

On the other hand, an inner peripheral edge 70″ of the baffle plate 70 is on an inner side of the outer peripheral edge 12′ of the stage 12, so as to be put on the stepped portion 80 formed in the outer peripheral edge portion of the stage 17.

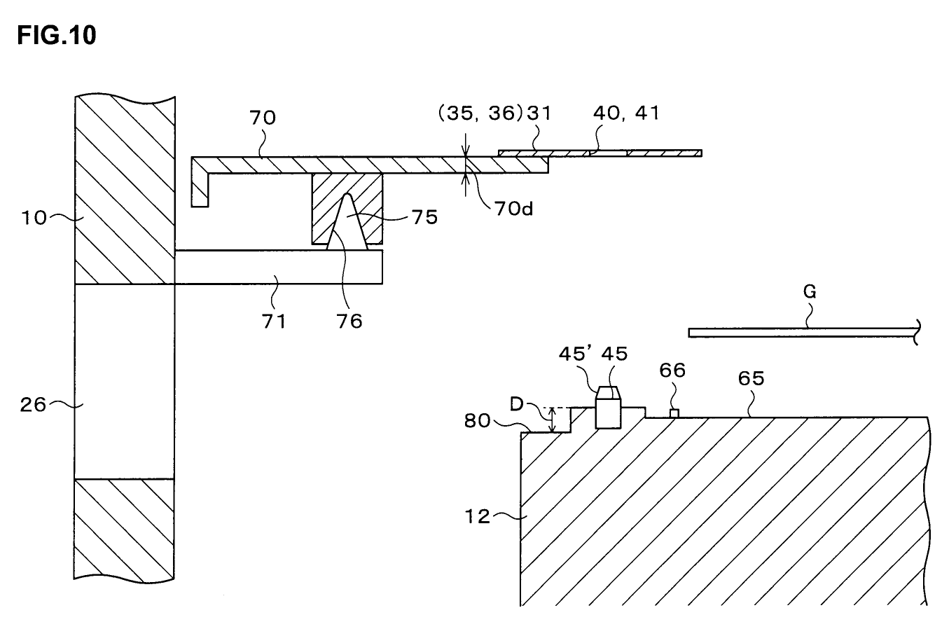

Also in the plasma processing apparatus 2 according to the second embodiment of the present invention as structured above, an opening 26 is first opened and a substrate G is carried into the process vessel 10. Then, as shown in FIG. 10, the substrate G is held above the stage 12 which is down at the standby position.

After the substrate G is thus carried in, the stage 12 is moved up from the standby position toward the processing position by the operation of a lift mechanism 14. In the course of this upward movement, the substrate G is first transferred onto the stage 12. Also in this case, the substrate G is placed on a recession 65 formed in a center portion of the stage 12. Further, the substrate G is positioned by a projection 66 provided on the recession 65.

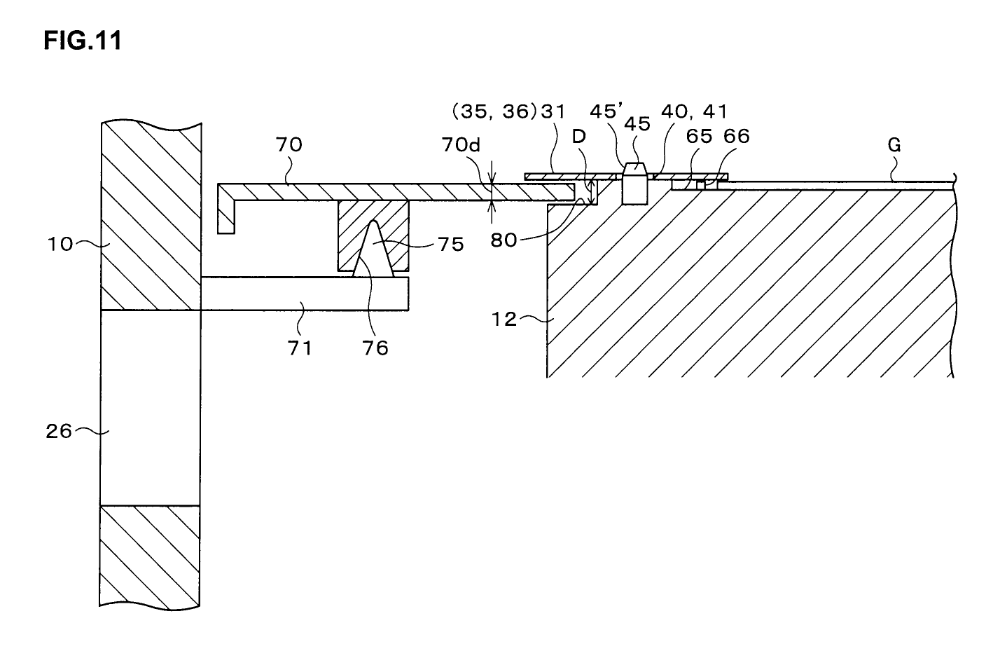

After the substrate G is thus transferred onto the stage 12, the stage 12 is further moved up, and as shown in FIG. 11, taper pins 45 provided on the upper surface of the stage 12 are inserted from under into circular guide holes 40 and guide holes 41 in a long hole shape provided in the mask members 35, 36. Consequently, the mask members 35, 36 move along conical upper half portions 45′ of the taper pins 45, so that the mask 12 is positioned. By such positioning of the mask 31, the outer peripheral edge portion of the substrate G placed on the stage 12 is covered by the mask 31.

In this case, the mask 31 is held on the baffle plate 70 to be horizontally movable. Therefore, when the taper pins 45 provided on the upper surface of the stage 12 are inserted in the circular guide holes 40 and the guide holes 41 in a long hole shape provided in the mask members 35, 36, the mask members 35, 36 are smoothly moved to predetermined positions on the stage 12. In this manner, the mask 31 is accurately positioned, which makes it possible to accurately cover the outer peripheral edge portion of the substrate G by the mask 31 with precision of, for example, about 1 mm to about 2 mm relative to the outer peripheral edge of the substrate G.

After the mask 31 is thus accurately positioned and transferred to the upper surface of the stage 12, the rear surface of the baffle plate 70 is then moved up by the stepped portion 80 formed in the outer peripheral edge portion of the stage 12, so that the baffle plate 70 is transferred onto the stage 12. Since the depth D of the stepped portion 80 is larger than the thickness 70d of the baffle plate 70 as described above, an upper surface of the baffle plate 70 and a rear surface of the mask 31 are apart from each other when the baffle plate 70 has been thus transferred onto the stage 12.

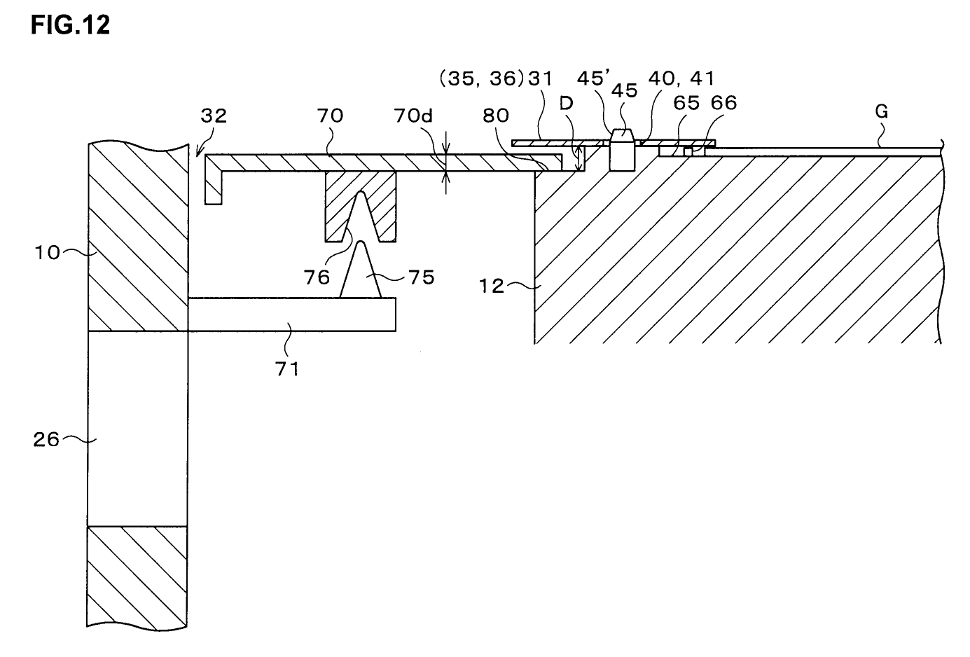

Then, when the stage 12 is moved up to the processing position by the operation of the lift mechanism 14, the baffle plate 70 is on an outer side of the mask 31 positioned and supported on the stage 12, as shown in FIG. 12.

Thereafter, process gas is supplied into the process vessel 10 through a shower plate 60 in a uniformly dispersed state. Further, a microwave of, for example, 2.45 GHz is introduced from waveguides 50 into the process vessel 10 via a plurality of dielectrics 57. In this manner, the process gas is turned into plasma in the process vessel 10, so that an amorphous silicon film is formed on a surface of the substrate G.

After the formation of the amorphous silicon film is finished, the supply of the process gas and the introduction of the microwave are stopped. Then, the stage 12 is moved down from the processing position to the standby position by the operation of the lift mechanism 14. This produces again the state where the baffle plate 70 is placed on the baffle plate holding members 71, the mask 31 is placed on the baffle plate 70, and the substrate G is held above the stage 12 as shown in FIG. 10. Thereafter, the opening 26 is opened, and the substrate G is carried out of the process vessel 10.

According to the plasma processing apparatus 2 of the second embodiment, similarly to the plasma processing apparatus 1 according to the first embodiment previously described, the mask 31 can be accurately positioned on the stage 12 without affected by the deviation of the positional relation between the process vessel 10 and the stage 12. This makes it possible to accurately form a non-film-forming region in the outer peripheral edge portion of the substrate G with precision of, for example, about 1 mm to about 2 mm relative to the outer peripheral edge of the substrate G.

In addition, according to the plasma processing apparatus 2 of the second embodiment, since the baffle plate 70 is positioned relative to the inner surface of the process vessel 10, a gap between the outer periphery of the baffle plate 70 and the inner surface of the process vessel 10 can be fixed, which makes it possible to suitably regulate the flow of the gas in the process vessel 10. Further, since the mask 31 and the baffle plate 70 are separate constituent members and at the processing position, the rear surface of the mask 31 is apart from the upper surface of the baffle plate 70, no stress occurs between the mask 31 and the baffle plate 70 even when the mask 31 and the baffle plate 70 are different in coefficient of thermal expansion. Further, it is possible to accurately maintain the position of the mask 31 positioned on the stage 12, without the thermal expansion of the baffle plate 70 affecting the mask 31. For example, even when a material of the mask 31 is alumina (coefficient of thermal expansion 7 to 8×10-6/° C.) and a material of the baffle plate 70 is aluminum (coefficient of thermal expansion 23 to 24×10-6/° C.), the positional deviation of the mask 31 due to the difference in coefficient of thermal expansion therebetween is avoided.

In the foregoing, the examples of preferred embodiments are described, but the present invention is not limited to the forms shown here.

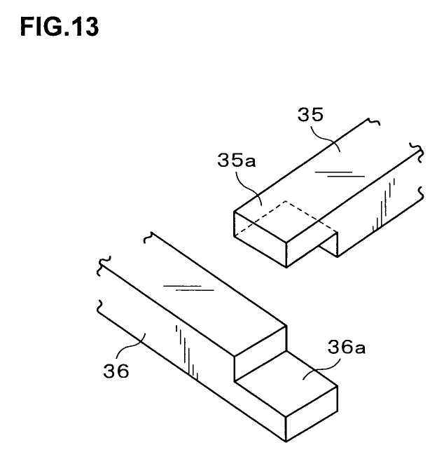

For example, in FIGS. 4(a) and 4(b), the example is described where the protrusion 35a′ is provided in one of the end portions 35a, 36a of the mask members 35, 36 and the recession 36a′ is provided in the other, but the structure where the protrusion 35a′ and the recession 36a′ are not provided in the end portions 35a, 36a of the mask members as shown in FIG. 13 may be adopted. Even without the protrusion 35a′ and the recession 36a′, the longitudinal end portions 35a, 36a of the mask members 35, 36 always maintain the state of being laid one on the other even when the mask members 35, 36 change in length due to the thermal expansion, provided that the longitudinal end portions 35a, 36a of the mask members 35, 36 are arranged to be laid one on the other vertically.

Further, the above embodiments describe the examples where the formation of the amorphous silicon film as an example of the plasma processing is performed, but the present invention is applicable not only to the formation of the amorphous silicon film but also to CVD processes of oxide film formation, polysilicon film formation, silane-ammonia processing, silane-hydrogen processing, oxide film processing, silane-oxygen processing, and others and also to an etching process.

In the above embodiments, the description is given, taking the plasma processing using a microwave as an example, but it goes without saying that the present invention is not limited to this and is also applicable to plasma processing using a radio-frequency voltage. Further, the substrate processed in the plasma processing of the present invention may be any of a semiconductor wafer, an organic EL substrate, a FDP (flat panel display) substrate, and the like.

The present invention is applicable to plasma processing performed in manufacturing fields of LCD substrates, semiconductors, and the like.

What is claimed is:

1. A plasma processing apparatus which applies plasma processing to a substrate placed on a stage by turning process gas supplied into a process vessel into plasma, the apparatus comprising:
a lift mechanism which, in the process vessel, moves down the stage to a standby position when the plasma processing is not performed and moves up the stage to a processing position when the plasma processing is performed;
a holding member detachably holding a mask which is to cover an outer peripheral edge portion of the substrate, between the standby position and the processing position; and
a positioning mechanism positioning the mask on the stage, wherein:
the mask is held while being horizontally movable without being positioned by said holding member; and
when the stage is moved up from the standby position toward the processing position, the mask is transferred from said holding member onto the stage, and the mask is positioned on the stage by said positioning mechanism.

2. The plasma processing apparatus according to claim 1, wherein
said positioning mechanism is made up of a taper pin provided on an upper surface of the stage and a guide hole provided in the mask to have the taper pin inserted therein.

3. The plasma processing apparatus according to claim 2, wherein
the guide hole is provided in plurality, and at least part of the guide holes is in a long hole shape.

4. The plasma processing apparatus according to claim 1, wherein
the mask is made up of a plurality of divided mask members.

5. The plasma processing apparatus according to claim 4, wherein
end portions of the plural divided mask members are arranged to be laid one on the other vertically.

6. The plasma processing apparatus according to claim 1, wherein
said holding member is fixed to an inner surface of the process vessel.

7. The plasma processing apparatus according to claim 1, wherein:
said holding member is made up of: a baffle holding member fixed to an inner surface of the process vessel; and a baffle plate detachably supported by the baffle holding member; and
when the stage is moved up from the standby position toward the processing position, the baffle plate is transferred onto the stage from the baffle holding member.

8. The plasma processing apparatus according to claim 7, wherein
the baffle plate is supported while being positioned relative to the inner surface of the process vessel.

9. The plasma processing apparatus according to claim 1, wherein
a recession for having the substrate placed thereon is formed in an upper surface of the stage.

10. The plasma processing apparatus according to claim 9, wherein
a projection for positioning the substrate is provided on the recession.
